(19) United States
(12) Patent Application Publication
(10) Pub. No.: US 2026/0353947 A1
(43) Pub. Date: Nov. 5, 2026

(54) DISPLAY PANEL AND DISPLAY APPARATUS

(71) Applicant: Wuhan Tianma Microelectronics Co., Ltd., Wuhan (CN)

(72) Inventor: Qin YUE, Wuham (CN)

(73) Assignee: Wuhan Tianma Microelectronics Co., Ltd., Wuhan (CN)

(21) Appl. No.: 19/235,510

(22) Filed: Jun. 11, 2025

(30) Foreign Application Priority Data
Mar. 4, 2025 (CN) 202510252749.3

(51) Int. Cl. H10K 59/131; H10K 59/80

(52) U.S. Cl. CPC H10K 59/131; H10K 59/80521

(57) ABSTRACT

The present application discloses a display panel and a display apparatus. The display panel comprises a substrate, a circuit layer and a cathode layer. The circuit layer is located on one side of the substrate. The cathode layer is located on one side of the circuit layer away from the substrate. The cathode layer comprises at least first-type cathodes and second-type cathodes, and the first-type cathode are spaced from the second-type cathode. The circuit layer comprises cathode power lines. The cathode power line comprises at least a first-type power line and a second-type power line. The first-type cathode is electrically connected to the first-type power line, and the second-type cathode is electrically connected to the second-type power line. The first-type power line receives a first cathode signal, and the second-type power line receives a second cathode signal.

### CROSS REFERENCE TO RELATED APPLICATION

The present application claims priority to Chinese Patent Application No. 202510252749.3 filed on Mar. 4, 2025, which is incorporated herein by reference in its entirety.

### TECHNICAL FIELD

The present application relates to the technical field of display technology, and particularly to a display panel and a display apparatus.

### BACKGROUND

Organic Light-Emitting Diode (OLED) display panels have characteristics such as self-luminous, high brightness, wide viewing angle, high contrast ratio, flexibility, and low energy consumption, and thus are widely used in display devices.

An OLED display panel is composed of a plurality of OLED elements with different light-emission colors. In the prior art, all OLED elements generally share one entire layer of cathode.

### SUMMARY

In an aspect, the present application provides a display panel, comprising: a substrate; a circuit layer, located on a side of the substrate; and a cathode layer, located on a side of the circuit layer away from the substrate, wherein the cathode layer comprises at least first-type cathodes and second-type cathodes, and the first-type cathode being spaced from the second-type cathode. The circuit layer comprises cathode power lines; the cathode power lines comprise at least a first-type power line and a second-type power line; the first-type cathodes are electrically connected to the first-type power line, and the second-type cathodes are electrically connected to the second-type power line; the first-type power line is configured to receive a first cathode signal, and the second-type power line is configured to receive a second cathode signal, an absolute value of voltage of the first cathode signal being larger than an absolute value of voltage of the second cathode signal; and the first-type power line comprises a first main line, and the second-type power line comprises a second main line, a width of the first main line being larger than a width of the second main line.

In another aspect, the present application provides a display apparatus comprising the display panel provided in any one of the embodiments of the present application.

It should be understood that, the content described herein is not intended to identify key or important features of embodiments of the application, nor is it intended to limit the scope of the application. Other features of the present application will become readily understood from the following description.

### BRIEF DESCRIPTION OF THE DRAWINGS

Drawings necessary for explaining embodiments of the present application are described briefly below to illustrate technical solutions of embodiments of the present application more clearly. Obviously, the drawings described below are merely some embodiments of the present application. Other figures can be obtained by those with ordinary skill in the art from the drawings without any inventive effort.

FIG. 1 shows a top view of a display panel according to an embodiment of the present application;

FIG. 2 shows a sectional view of the display panel taken along BB′ in FIG. 1;

FIG. 3 shows a structural diagram of a pixel circuit in the related art;

FIG. 4 shows a driving timing diagram of the pixel circuit shown in FIG. 3;

FIG. 5 shows a top view of another display panel according to an embodiment of the present application;

FIG. 6 shows a sectional view of the display panel taken along CC′ in FIG. 5;

FIG. 7 shows a top view of another display panel according to an embodiment of the present application;

FIG. 8 shows a top view of another display panel according to an embodiment of the present application;

FIG. 9 shows a top view of another display panel according to an embodiment of the present application;

FIG. 10 shows a sectional view of the display panel taken along EE′ in FIG. 9;

FIG. 11 shows a top view of another display panel according to an embodiment of the present application;

FIG. 12 shows a top view of another display panel according to an embodiment of the present application;

FIG. 13 shows a top view of another display panel according to an embodiment of the present application;

FIG. 14 shows a top view of another display panel according to an embodiment of the present application;

FIG. 15 shows a top view of another display panel according to an embodiment of the present application;

FIG. 16 shows a top view of another display panel according to an embodiment of the present application;

FIG. 17 shows a top view of another display panel according to an embodiment of the present application;

FIG. 18 shows a top view of another display panel according to an embodiment of the present application;

FIG. 19 shows a top view of another display panel according to an embodiment of the present application; and

FIG. 20 shows a structural diagram of a display apparatus according to an embodiment of the present application.

### DETAILED DESCRIPTION

In order to enable those skilled in the art to better understand the solutions of the present application, the technical solutions in the embodiments of the present application will be clearly and completely described below with reference to the accompanying drawings in the embodiments of the present application, and it is obvious that the described embodiments are only some embodiments of the present application, but not all embodiments. Based on the embodiments in the present application, all other embodiments obtained by those skilled in the art without inventive effort should belong to the scope of protection of the present application.

It will be apparent to those skilled in the art that various modifications and variations can be made in the present application without departing from the gist or scope of the present application. Accordingly, the present application is intended to cover modifications and variations thereof that fall within the scope of the corresponding claims (claimed technical solutions) and their equivalents. It should be noted that, the implementation methods provided in the embodiments of this application may be mutually combined without causing contradictions.

First of all, unless otherwise defined, technical terms or scientific terms used in the present application should have their ordinary meanings as understood by those of ordinary skill in the art to which the present application belongs. The use of “first”, “second” and similar words in the present application does not indicate any order, quantity, or importance, but is merely intended to distinguish different components. The term “comprising” and similar words mean that elements or articles that appear before the word encompass elements or articles that appear after the word and their equivalents, but do not exclude other elements or articles. The words such as “connected” or “connected to” are not limited to physical or mechanical connections, but may include electrical connections, whether direct or indirect. Similar terms such as “upper”, “lower”, “left” and “right” are used only to indicate a relative positional relationship, and when the absolute position of the object to be described is changed, the relative positional relationship may also be changed accordingly. Furthermore, the shapes and sizes of the components in the drawings do not reflect true scale and are intended only to illustrate the present application.

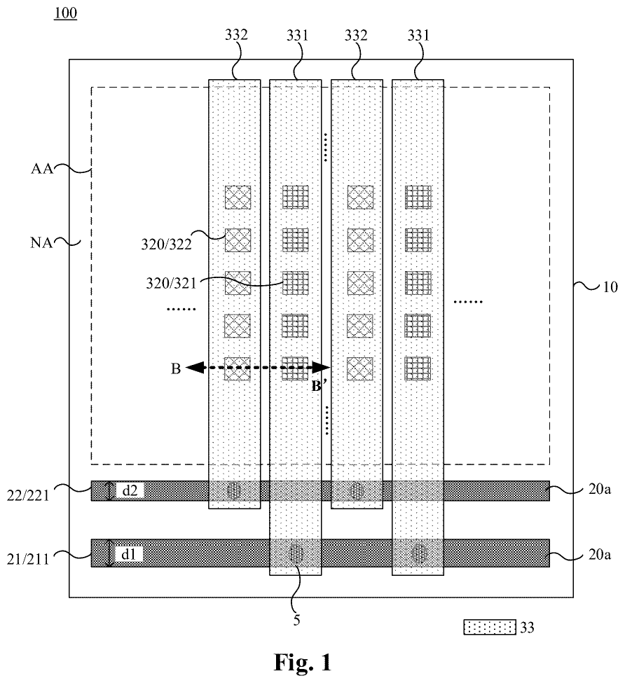

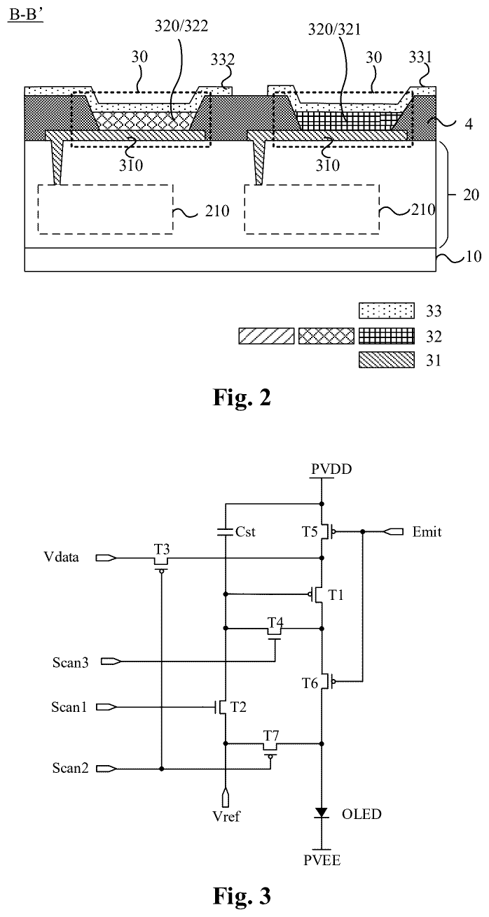

FIG. 1 shows a top view of a display panel according to an embodiment of the present application. FIG. 2 shows a sectional view of the display panel taken along BB′ in FIG. 1. As shown in FIGS. 1 and 2, the display panel 100 provided in embodiments of the present application includes a substrate 10, a circuit layer 20, and a cathode layer 33. The circuit layer 20 is located on the side of the substrate 10. The cathode layer 33 is located at the side of the circuit layer 20 away from the substrate 10. The cathode layer 33 includes at least first-type cathodes 331 and second-type cathodes 332, and the first-type cathode 331 and the second-type cathode 332 are spaced from each other. The circuit layer 20 includes cathode power lines 20a. The cathode power line 20a includes at least a first-type power line 21 and a second-type power line 22. The first-type cathode 331 is electrically connected to the first-type power line 21, and the second-type cathode 332 is electrically connected to the second-type power line 22. The first-type power line 21 receives a first cathode signal, and the second-type power line 22 receives a second cathode signal. An absolute value of voltage of the first cathode signal is larger than an absolute value of voltage of the second cathode signal. The first-type power line 21 includes a first main line 211, and the second-type power line 22 includes a second main line 221. The width d1 of the first main line 211 is larger than the width d2 of the second main line 221.

The circuit layer 20 is mainly used for forming circuit structures such as pixel circuits, gate driving circuits, multiplexing circuits, and electrostatic protection circuits. The pixel circuits are electrically connected to the OLED elements, and one pixel circuit may be used for driving at least one OLED element to emit light. The gate driving circuits are electrically connected to the pixel circuits and are used for enabling the pixel circuits row by row, so as to light up the OLED elements row by row through the pixel circuits and carry out the display of a frame of image. The multiplexing circuit and the electrostatic protection circuit may be set as needed. The multiplexing circuit mainly solves the problem that the number of signal lines does not match the number of driving chip pins, and the electrostatic protection circuit is for electrostatic protection to ensure reliability of the display panel.

As shown in FIG. 2, the display panel includes an anode layer 31 located on the side of the circuit layer 20 away from the substrate 10, an organic light-emission layer 32 located on the side of the anode layer 31 away from the substrate 10, and the cathode layer 33 located on the side of the organic light-emission layer 32 away from the substrate 10. The anode layer 31 includes a plurality of independent anode structures 310, and the organic light-emission layer 32 includes a plurality of organic light-emission units 320. A pixel defining layer 4 is provided between adjacent organic light-emission units 320. The cathode layer 33 includes cathode structures. The organic light-emission unit 320, together with the anode structure 310 and cathode structure on two opposite sides thereof, constitute an OLED element 30. The anode structure 310 is electrically connected to the pixel circuit 210, and the cathode structure is electrically connected to the cathode power line.

Referring to FIG. 1, in the present embodiment, the cathode structure in the cathode layer 33 is divided into at least two types. That is, the cathode layer 33 includes at least first-type cathodes 331 and second-type cathodes 332, and the first-type cathode 331 and the second-type cathode 332 are spaced from each other. Accordingly, the cathode power lines 20a include at least a first-type power line 21 and a second-type power line 22. The first-type cathodes 331 are electrically connected to the first-type power line 21, and the second-type cathodes 332 are electrically connected to the second-type power line 22. The first-type power line 21 receives a first cathode signal, and the second-type power line 22 receives a second cathode signal. In this manner, the first cathode signal may be transmitted to the first-type cathode 331 via the first-type power line 21 and the second cathode signal may be transmitted to the second-type cathode 332 via the second-type power line 22 to realize independent control of the cathode signal of the first-type cathode 331 and the cathode signal of the second-type cathode 332. Accordingly, the values of the first cathode signal and the second cathode signal can be adaptively configured according to the actual operating voltage requirements of the OLED elements corresponding to the first-type cathode 331 and the OLED elements corresponding to the second-type cathode 332, thereby reducing power consumption waste and reducing the overall power consumption of the display panel.

For example, FIG. 3 is a structural diagram of a pixel circuit in the related art. As shown in FIG. 3, the pixel circuit includes a driving transistor T1, an initialization transistor T2, a data writing transistor T3, a threshold compensation transistor T4, a first light-emission control transistor T5, a second light-emission control transistor T6, a reset transistor T7, and a storage capacitor Cst, which may constitute a 7T1C pixel circuit. Optionally, the driving transistor T1, the data writing transistor T3, the first light-emission control transistor T5, the second light-emission control transistor T6, and the reset transistor T7 are LTPS transistors to reduce the power consumption of the pixel circuit and shorten the response time of the pixel circuit. The initialization transistor T2 and the threshold compensation transistor T4 are IGZO transistors to reduce drain current of the initialization transistor T2 and the threshold compensation transistor T4, and reduce an impact of the drain current thereof on gate potential of the driving transistor T1, thereby further optimizing the performance of the pixel circuit.

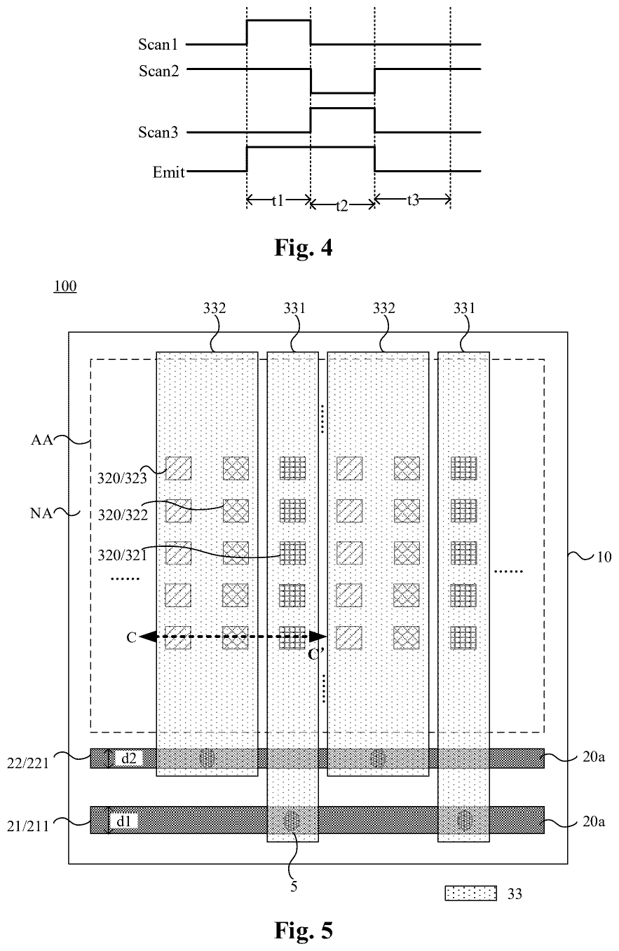

FIG. 4 is a driving timing diagram of the pixel circuit shown in FIG. 3. As shown in FIGS. 3 and 4, a driving process of the pixel circuit includes an initialization stage t1, a data writing stage t2, and a light-emission stage t3. Specifically, in the initialization stage t1, the initialization transistor T2 is turned on under the control of a first scan control signal transmitted by a first scan control signal terminal Scan1, and an initialization signal of the initialization signal terminal Vref is written to a gate of the driving transistor T1 to initialize the gate of the driving transistor T1. In the data writing stage t2, the data writing transistor T3 is turned on under the control of a second scan control signal transmitted by a second scan control signal terminal Scan2, the threshold compensation transistor T4 is turned on under the control of a third scan control signal transmitted by a third scan control signal terminal Scan3, and the driving transistor T1 is turned on because gate-source voltage satisfies an activation condition, such that the data writing transistor T3 writes a data signal of a data signal terminal to the gate of the driving transistor T1, and the threshold compensation transistor T4 transmits a threshold voltage compensation value of the driving transistor T1 to the gate of the driving transistor T1. In addition, in the data writing stage t2, the reset transistor T7 is turned on under the control of the second scan control signal transmitted by the second scan control signal terminal Scan 2, and writes the initialization signal of the initialization signal terminal Vref to an anode of the OLED, thereby resetting an anode voltage of the OLED. In the light-emission stage t3, the first light-emission control transistor T5 and the second light-emission control transistor T6 are turned on under the control of a light-emission control signal of a light-emission control signal terminal Emit. Since the storage capacitor Cst stores the gate potential of the driving transistor T1, the driving transistor T1 generates a driving current based on the gate potential and a potential of a first power supply signal terminal PVDD, and drives the OLED to emit light. In FIG. 3, PVEE is a second power supply signal terminal for providing a cathode signal to a cathode of the OLED, and a potential of the second power supply signal terminal is lower than a potential of the first power supply signal terminal.

Referring to FIG. 3, an OLED element of a light-emission color corresponds to a sub-pixel of the light-emission color, and a power consumption of the sub-pixel is positively correlated with (PVDD-PVEE) * I_{OLED}, wherein PVDD represents a voltage of the first power supply signal terminal PVDD, PVEE represents a voltage of the second power supply signal terminal, PVDD-PVEE can represent an operating voltage of the OLED element, and I_{OLED} represents current flowing through the OLED element. Generally, the PVDD voltages corresponding to all OLED elements are the same. It is assumed that cathode signal voltage (PVEE) required by the OLED element with the largest operating voltage among all OLED elements is −4V, while the cathode signal voltage actually required by a certain type of OLED element is only −1V. In embodiments of the present application, by dividing the cathode layer 33 into at least two types of cathodes, and different types of cathodes being arranged spaced from each other, for example, the first-type cathode 331 and the second-type cathode 332 being spaced from each other, the first-type power line 21 transmitting a first cathode signal to the first-type cathode 331, and the second-type power line 22 transmitting a second cathode signal to the second-type cathode 332, the values of the first cathode signal and the second cathode signal can be adaptively configured according to the actual operating voltage requirements of different OLED elements, thereby reducing power consumption waste and reducing the overall power consumption of the display panel.

It should be noted that, the arrangement of the organic light-emission units 320 (that is, the pixel arrangement) shown in FIG. 1 is merely for illustration, and does not limit the embodiments of the present application. The embodiments of the present application are applicable to any type of pixel arrangement pattern. In addition, the structure and operation timing of the pixel circuit shown in FIGS. 3 and 4 are merely for illustration, and do not limit the embodiments of the present application. The embodiments of the present application are applicable to pixel circuit of any current driving type.

Referring to FIGS. 1 and 2, a cathode power line 20a may be provided in the circuit layer 20. Referring to FIG. 1, cathodes (such as the first-type cathodes 331 and the second-type cathodes 332) in the cathode layer 33 may be electrically connected to the corresponding cathode power line 20a by vias 5.

Referring to FIG. 1, the display panel 100 includes a display area AA and a non-display area NA located on at least one side of the display area AA. Optionally, the first main line 211 of the first-type power line 21 and the second main line 221 of the second-type power line 22 are provided in the non-display area NA, so as to reduce the wiring difficulty.

Further, as shown in FIG. 1, in the present embodiment, the width d1 of the first main line 211 is larger than the width d2 of the second main line 221. Referring to FIG. 1, the cathode signal is supplied by the power board or driver chip and then transmitted to the corresponding cathode in the cathode layer 33 via the cathode power line 20a. It can be understood that, the cathode power line 20a has a certain resistance, and thus the voltage of the cathode signal will be partially drop on the cathode power line 20a. That is, there is an IR drop (voltage drop) on the cathode power line, which will generate power consumption. Therefore, the power consumption of the sub-pixel includes not only power consumption of the OLED element, but also power consumption on the corresponding cathode power line 20a (of course, other wirings will also have power consumption, which is not considered here), and the power consumption of the display panel includes power consumption of all OLED elements and power consumption on all cathode power lines 20a. Considering that the power consumption of the OLED element is necessary for realizing the display, and the power consumption on the cathode power line 20a is adjustable, the power consumption on the cathode power line 20a may be reduced by reducing the impedance thereof to reduce the power consumption of the display panel.

Optionally, the impedance of the cathode power line 20a may be reduced by increasing the width thereof to reduce the power consumption.

In this embodiment, the absolute value of voltage of the first cathode signal transmitted by the first-type power line 21 is larger than the absolute value of voltage of the second cathode signal transmitted by the second-type power line 22, which indicates that the operating voltage (PVDD-PVEE) of the sub-pixel corresponding to the first-type power line 21 is larger than the operating voltage of the sub-pixel corresponding to the second-type power line 22. Therefore, the current flowing through the OLED element in the sub-pixel corresponding to the first-type power line 21 is larger than the current flowing through the OLED element in the sub-pixel corresponding to the second-type power line 22, i.e., the current in the first-type power line 21 is greater than the current in the second-type power line 22. Further, since the power consumption of the wiring is positively correlated with I²R, and the current on the first-type power line 21 is greater than the current on the second-type power line 22, the power consumption reduction degree of the first-type power line 21 is larger than that of the second-type power line 22 when the impedance reduction degree of the first-type power line 21 is the same as that of the second-type power line 22. In view of this, since the wiring space in the display panel is very limited, in this embodiment, by setting the width of the first main line 211 to be larger than the width of the second main line 221, the impedance of the first-type power line 21 may be reduced to a larger extent, and thus the power consumption thereof may be reduced to a larger extent. In this manner, the power consumption on all the cathode power lines 20a may be reduced to a larger extent, and finally the power consumption of the display panel may be reduced to a larger extent. Of course, if the wiring space of the display panel is sufficient, the cathode power lines 20a each may be set to have a relatively large width.

For example, assuming that the current in the first-type power line 21 is 10 μA, the current on the second-type power line 22 is 8 μA, and the original design impedance of the first-type power line 21 and the second-type power line 22 is R, the total power of the first-type power line 21 and the second-type power line 22 is P=100 R+64 R=164 R. If the impedance of the first-type power line 21 remains unchanged and the impedance of the second-type power line 22 decreases by 20%, the total power of the first-type power line 21 and the second-type power line 22 P=100 R+64*0.8 R=151.2 R; if the impedance of the first-type power line 21 decreases by 10% and the impedance of the second-type power line 22 decreases by 10%, the total power thereof P=100* 0.9 R+64*0.9 R=147.6 R; and if the impedance of the first-type power line 21 decreases by 20% and the impedance of the second-type power line 22 remains unchanged, the total power thereof P=100*0.8 R+64 R=144 R. It can be seen that, by reducing the impedance of the first-type power line 21 to a larger extent, the power consumption on all cathode power lines can be reduced to a larger extent, and then the power consumption of the display panel can be reduced to a larger extent.

In a word, in embodiments of the present application, by providing the cathode layer including at least first-type cathodes and second-type cathodes spaced from each other, the cathode power lines in the circuit layer including at least a first-type power line and a second-type power line, the first-type cathode being electrically connected to the first-type power line, the second-type cathode being electrically connected to the second-type power line, the first-type power line receiving and transmitting a first cathode signal, and the second-type power line receiving and transmitting a second cathode signal, independent control of the cathode signal of the first-type cathode and the cathode signal of the second-type cathode can be realized. Accordingly, the values of the first cathode signal and the second cathode signal can be adaptively configured according to the actual operating voltage requirements of the OLED elements corresponding to the first-type cathode and the OLED elements corresponding to the second-type cathode, thereby reducing power consumption waste and lowering the overall power consumption of the display panel. In addition, according to the magnitude relationship between the first cathode signal and the second cathode signal, the width of the first main line of the first-type power line and the width of the second main line of the second-type power line may be adaptively set with difference therebetween. For example, when the absolute value of voltage of the first cathode signal transmitted by the first-type power line is larger than the absolute value of voltage of the second cathode signal transmitted by the second-type power line, the width of the first main line is set to be larger than the width of the second main line, such that impedance of the first-type power line is lower. In this manner, within the limited wiring space of the display panel, power consumption generated by all cathode power lines can be reduced to a larger extent, and the power consumption of the display panel can be significantly reduced accordingly.

Referring to FIGS. 1 and 2, optionally, the organic light-emission units 320 include at least first-type light-emission units 321 and second-type light-emission units 322, and the light-emission color of the first-type light-emission units 321 is different from the light-emission color of second-type light-emission units 322; and each of the first-type cathodes 331 covers at least one first-type light-emission unit 321, and each of the second-type cathodes 332 covers at least one second-type light-emission unit 322.

Specifically, according to different display requirements, the display panel may include sub-pixels of at least two colors, and correspondingly, the organic light-emission units 320 includes at least two types of organic light-emission units with different light-emission colors, i.e., the first-type light-emission units 321 and the second-type light-emission units 322.

As an example, FIG. 1 illustrates that the organic light-emission units 320 include the first-type light-emission units 321 and the second-type light-emission units 322, but in other embodiments, the organic light-emission units 320 may include more types of light-emission units, which is not specifically defined by the embodiments of the present application.

Further, according to the arrangement of the sub-pixels (organic light-emission units 320), each of the first-type cathodes 331 covers at least one first-type light-emission unit 321, and each of the second-type cathodes 332 covers at least one second-type light-emission unit 322.

For example, in FIG. 1, the first-type light-emission units 321 are arranged in a column and the second-type light-emission units 322 are arranged in a column. Correspondingly, one first-type cathode 331 may cover the first-type light-emission units 321 in a same column, and one second-type cathode 332 may cover the second-type light-emission units 322 in a same column. In other embodiments, different first-type light-emission units 321/second-type light-emission units 322 may not be provided adjacent to each other. At this time, one first-type cathode 331 may cover only one first-type light-emission unit 321, and one second-type cathode 332 may cover only one second-type light-emission unit 322, which will be illustrated later.

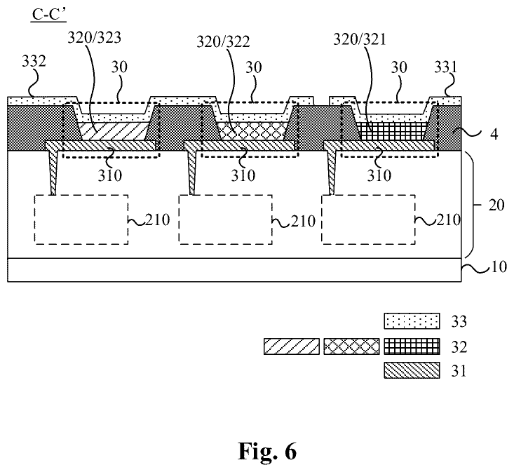

FIG. 5 is a top view of another display panel according to an embodiment of the present application. FIG. 6 is a sectional view of the display panel taken along CC′ in FIG. 5. As shown in FIGS. 5 and 6, optionally, in addition to the first-type light-emission units 321 and the second-type light-emission units 322, the organic light-emission units 320 further include third-type light-emission units 323, the light-emission color of the third-type light-emission units 323 is different from the light-emission color of the first-type light-emission units 321 and the light-emission color of the second-type light-emission units 322, and one second-type cathode 332 covers at least one second-type light-emission unit 322 and at least one third-type light-emission unit 323.

Specifically, when the organic light-emission units 320 include different organic light-emission units with three or more light-emission colors, the organic light-emission units 320 may be divided into two groups according to the actual required operating voltages of the OLED elements corresponding to the respective organic light-emission units 320, such that the operating voltages of the OLED elements corresponding to the organic light-emission units 320 in each group are similar or even the same. Then, the first-type cathode 331 covers one group of the organic light-emission units, and the second-type cathode 332 covers the other group of the organic light-emission units. In this manner, not only the power consumption waste can be reduced, but also the difficulty in dividing the cathode layer can be reduced, the number of cathode power lines can be decreased, and wiring difficulty thereof can be reduced.

As an example, referring to FIG. 5, the present embodiment illustrates that the organic light-emission units 320 include the first-type light-emission units 321, the second-type light-emission units 322, and the third-type light-emission units 323, wherein the operating voltages of the OLED elements corresponding to the second-type light-emission units 322 and the third-type light-emission units 323 are the same or similar, and the operating voltage of the OLED elements corresponding to the first-type light-emission units 321 is greatly different from the aforesaid two. In this case, optionally, one first-type cathode 331 may cover at least one first-type light-emission unit 321, and one second-type cathodes 332 may cover at least one second-type light-emission unit 322 and at least one third-type light-emission unit 323.

It should be noted that, the number of organic light-emission units covered by the cathode is specifically determined by the arrangement of the organic light-emission units 320, and the arrangement pattern shown in FIG. 5 is not a unique one.

Further, optionally, the first-type light-emission units 321 are blue light-emission units, and one type of the second-type light-emission units 322 and the third-type light-emission units 323 are green light-emission units, and the other type are red light-emission units.

Specifically, color display can be realized by providing the organic light-emission units 320 including organic light-emission units of three colors: red, green, and blue. Further, since the operating voltage required for the blue OLED is relatively high, and the operating voltages required for the red OLED and the green OLED are similar, it may be set that the first-type light-emission units 321 are blue light-emission units, either the second-type light-emission units 322 or the third-type light-emission units 323 are green light-emission units, and the other ones of the second-type light-emission units 322 and the third-type light-emission units 323 are red light-emission units. Then, the first-type cathode 331 covers at least one blue light-emission unit, and the second-type cathode 332 covers at least one green light-emission unit and at least one red light-emission unit to reduce waste of power consumption, decrease the number of cathode power lines, and reduce wiring difficulty thereof.

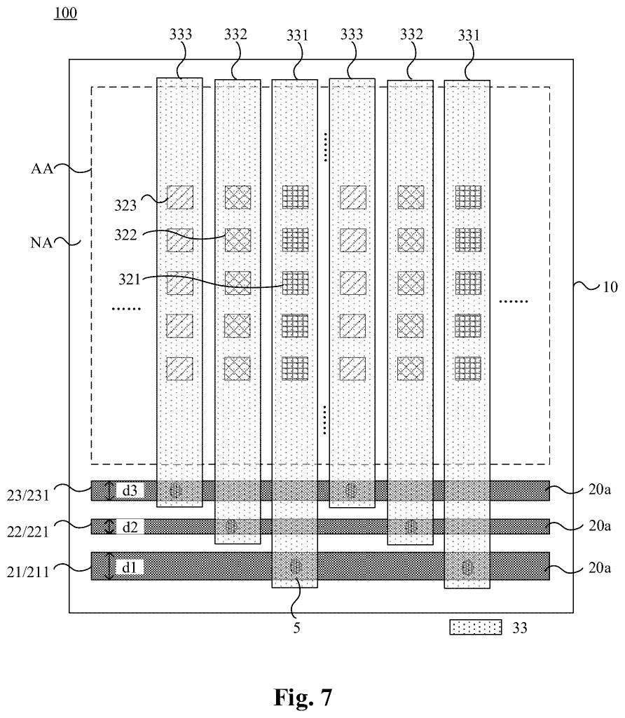

FIG. 7 is a top view of another display panel according to an embodiment of the present application. As shown in FIG. 7, in other embodiments, when the organic light-emission units 320 further include third-type light-emission units 323 with light-emission color different from the light-emission color of the first-type light-emission units 321 and the light-emission color of the second-type light-emission units 322, optionally, the cathode layer 33 further includes a third-type cathode 333 arranged spaced from the first-type cathode 331 and the second-type cathode 332, and one third-type cathode 333 covers at least one third-type light-emission unit 323. The cathode power line 20a further includes a third-type power line 23, and the third-type cathode 333 is electrically connected to the third-type power line 23. The third-type power line 23 receives a third cathode signal. An absolute value of voltage of the third cathode signal is less than an absolute value of voltage of the first cathode signal. The third-type power line 23 includes a third main line 231, and a width d3 of the third main line 231 is less than a width d1 of the first main line 211.

Specifically, when the organic light-emission units 320 include different organic light-emission units with three or more light-emission colors, the cathode layer 33 may be divided into several types of cathodes to match the number of colors, and correspondingly, the cathode power line 20a includes several types of cathode power lines to match the number of colors. In this manner, by adaptively adjusting the cathode signal magnitude transmitted via each type of cathode power line according to the actual operating voltage requirements of different OLED elements, power consumption waste can be minimized, and the overall power consumption of the display panel can be reduced.

For example, referring to FIG. 7, the present embodiment illustrates that the organic light-emission units 320 include the first-type light-emission units 321, the second-type light-emission units 322, and the third-type light-emission units 323; correspondingly, the cathode layer 33 includes the first-type cathodes 331, the second-type cathodes 332, and the third type cathodes 333; one first-type cathodes 331 covers at least one first-type light-emission unit 321, one second-type cathodes 332 covers at least one second-type light-emission unit 322, and one third type cathodes 333 covers at least one third type light-emission unit 323; correspondingly, the cathode power lines 20a include the first-type power line 21, the second-type power line 22, and the third-type power line 23; and the first-type power line 21 transmits the first cathode signal to the first-type cathode 331, the second-type power line 22 transmits the second cathode signal to the second-type cathode 332, and the third-type power line 23 transmits the third cathode signal to the third-type cathode 333. In this manner, independent control of cathode signals for OLEDs with different light-emission colors can be achieved. By adaptively adjusting the cathode signal magnitude transmitted via each cathode power line according to the actual operating voltage requirements of different OLED elements, power consumption waste can be minimized to the greatest extent, and the overall power consumption of the display panel can be reduced.

Further, with reference to the above explanation, since the absolute value of voltage of the first cathode signal is larger than the absolute value of voltage of the third cathode signal, by setting the width d3 of the third main line 231 of the third-type power line 23 to be less than the width d1 of the first main line 211 of the first-type power line 21, the power consumption of the cathode power line 20a can be reduced to a larger extent in a limited wiring space, thereby reducing the power consumption of the display panel.

Referring to FIG. 7, optionally, the third main line 231 is located in the non-display area NA, whereby the wiring difficulty can be reduced.

Referring to FIG. 7, optionally, the first-type light-emission units 321 are blue light-emission units, the second-type light-emission units 322 are green light-emission units, and the third-type light-emission units 323 are red light-emission units. An absolute value of voltage of the third cathode signal is larger than or equal to an absolute value of voltage of the second cathode signal. A width d3 of the third main line 231 is larger than or equal to a width d2 of the second main line 221.

Specifically, the operating voltage required by the red OLED is usually slightly larger than or equal to the operating voltage required by the green OLED. When the second-type light-emission units 322 are green light-emission units and the third-type light-emission units 323 are red light-emission units, the absolute value of voltage of the third cathode signal may be set to be larger than or equal to the absolute value of voltage of the second cathode signal, which may be set according to actual needs, and the embodiments of the present application are not limited thereto. Adaptively, when the absolute value of voltage of the third cathode signal is larger than the absolute value of voltage of the second cathode signal, the width d3 of the third main line 231 may be set to be larger than the width d2 of the second main line 221; and when the absolute value of voltage of the third cathode signal is equal to the absolute value of voltage of the second cathode signal, the width d3 of the third main line 231 may be set to be equal to the width d2 of the second main line 221.

In specific implementation, when the actual operating voltage of the red OLED is larger than the actual operating voltage of the green OLED, referring to FIG. 7, it may be set that the cathode layer 33 includes the first-type cathode 331, the second-type cathode 332, and the third-type cathode 333; one first-type cathode 331 covers at least one blue light-emission unit (first-type light-emission unit 321), one second-type cathode 332 covers at least one green light-emission unit (second-type light-emission unit 322), and one third-type cathode 333 covers at least one red light-emission unit (third-type light-emission unit 323); the width of the first main line 211 is larger than the width of the third main line 231; and the width of the third main line 231 is larger than the width of the second main line 221. In this manner, the corresponding cathode signal may be independently set according to the actual operating voltage of each OLED element, thereby reducing the waste of power consumption. In addition, the power consumption generated on the cathode power line can be reduced to a larger extent in the limited wiring space, thereby reducing the power consumption of the display panel to a larger extent.

Alternatively, when the actual operating voltage of the red OLED is equal to the actual operating voltage of the green OLED, referring to FIG. 5, it may be set that the cathode layer 33 includes the first-type cathodes 331 and the second-type cathodes 332; one first-type cathode 331 covers at least one blue light-emission unit (first-type light-emission unit 321), and one second-type cathode 332 covers at least one green light-emission unit (second-type light-emission unit 322) and at least one red light-emission unit (third-type light-emission unit 323). In this manner, not only the waste of power consumption, the power consumption generated on the cathode power line, and the power consumption of the display panel can be reduced, but also the wiring number and wiring difficulty can be reduced as well.

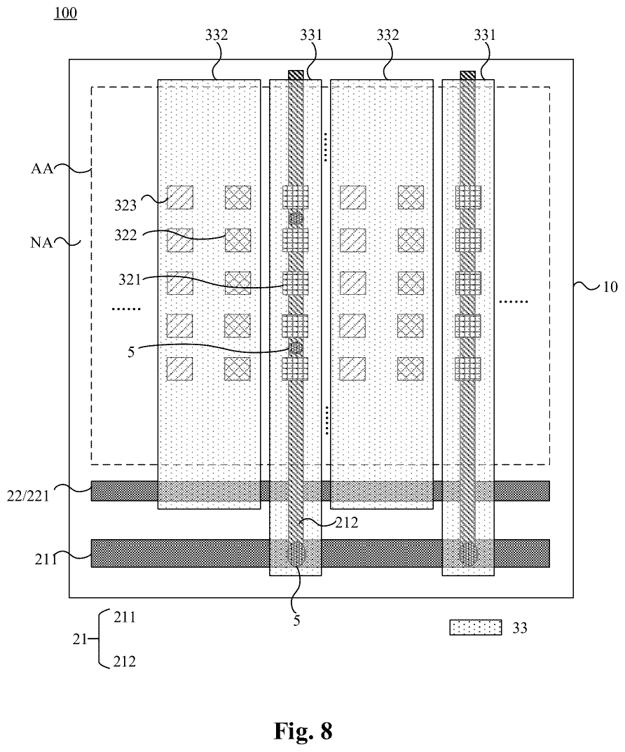

FIG. 8 is a top view of another display panel according to an embodiment of the present application. As shown in FIG. 8, optionally, the first-type power line 21 further includes a plurality of first branch lines 212, an extension direction of the first branch lines 212 intersects an extension direction of the first main line 211, and each of the plurality of first branch lines 212 is electrically connected to the first main line 211. The first main line 211 is located in the non-display area NA, and the first branch lines 212 pass through the display area AA.

Specifically, by providing the plurality of first branch lines 212 passing through the display area AA, and the plurality of first branch lines 212 being electrically connected to the first main line 211 to form the first-type power line 21, the impedance of the first-type power line 21 can be further reduced, and the power consumption generated by the first-type power line 21 can be reduced. Moreover, since the first main line 211 and the first branch lines 212 are distributed in different areas, the wiring difficulty can be reduced. Further, with reference to the above explanation, since the absolute value of voltage of the first cathode signal received by the first-type power line 21 is the largest, for the first-type power line 21, it is set that the first main line 211 and the plurality of first branch lines 212 are electrically connected to each other so as to reduce the impedance of the first-type power line 21. Thus, the power consumption on the cathode power line can be reduced to a larger extent, thereby reducing the power consumption of the display panel to a larger extent.

It should be noted that, FIG. 8 illustrates that the cathode layer 33 includes only the first-type cathode 331 and the second-type cathode 332 as an example. In the case where the cathode layer 33 includes a larger number of cathodes, for example, the first-type cathode 331, the second-type cathode 332 and the third-type cathode 333, the first-type power line 21 includes a plurality of branch lines may also be designed.

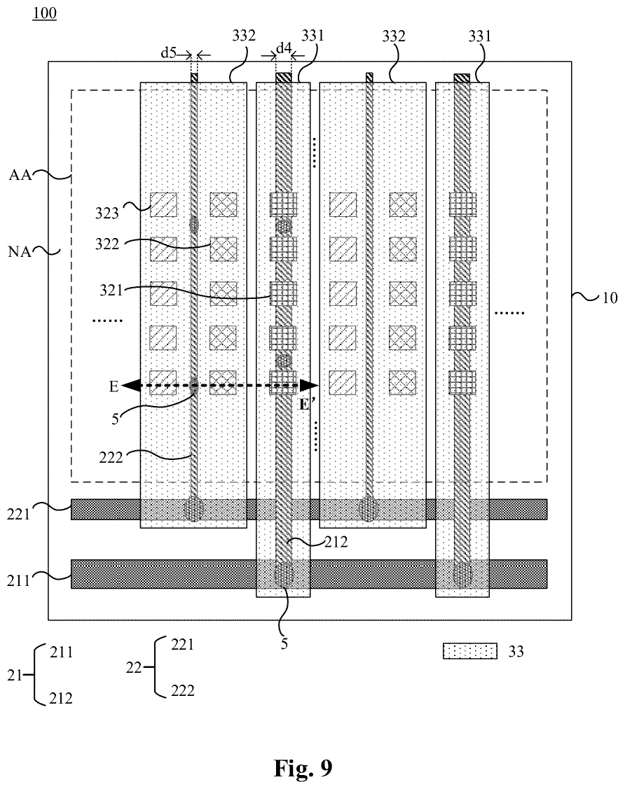

FIG. 9 is a top view of another display panel according to an embodiment of the present application. As shown in FIG. 9, optionally, the second-type power line 22 further includes a plurality of second branch lines 222, an extension direction of the second branch lines 222 intersects an extension direction of the second main line 221, and each of the plurality of second branch lines 222 is electrically connected to the second main line 221. The second main line 221 is located in the non-display area NA, and the second branch lines 222 pass through the display area AA.

Specifically, by providing the plurality of second branch lines 222 passing through the display area AA, and the plurality of second branch lines 222 being electrically connected to the second main line 221 to form the second-type power line 22, the impedance and power consumption of the second-type power line 22 can be further reduced, and the power consumption of the display panel can be reduced accordingly. Moreover, since the second main line 221 and the second branch lines 222 are distributed in different areas, the wiring difficulty can be reduced.

As shown in FIG. 9, optionally, a width d4 of the first branch line 212 is larger than a width d5 of the second branch line 222.

Similar to the design concept of the widths of the first main line 211 and the second main line 221, by setting the width d4 of the first branch line 212 to be larger than the width d5 of the second branch line 222, the power consumption generated on all the cathode power lines can be reduced to a larger extent, and the power consumption of the display panel can be reduced to a larger extent accordingly.

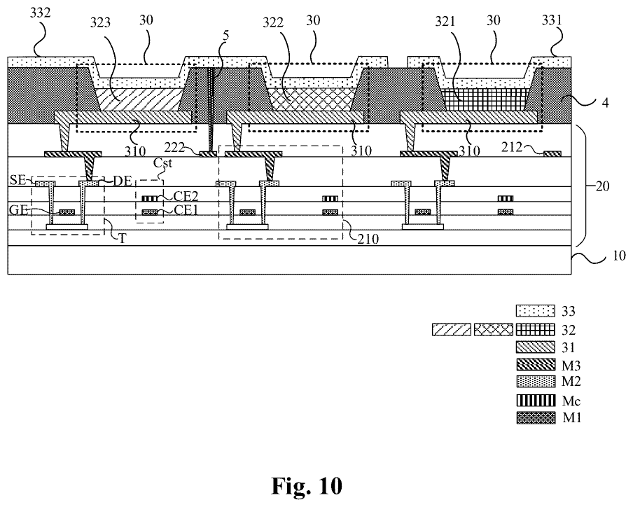

FIG. 10 is a sectional view of the display panel taken along EE′ in FIG. 9. As shown in FIGS. 9 and 10, optionally, the first branch line 212 and the second branch line 222 are located in a same film layer and have a same extension direction.

Specifically, referring to FIG. 9, since the extension direction of the first main line 211 intersects the extension direction of the first branch line 212, and the extension direction of the second main line 221 intersects the extension direction of the second branch line 222, by providing the first main line 211 and the second main line 221 extending in a same direction, and providing the first branch line 212 and the second branch line 222 extending in another same direction, wiring difficulty can be reduced. Further, the first main line 211 and the second main line 221 having the same extension direction may be provided in a same film layer, and the first branch line 212 and the second branch line 222 having the same extension direction may be provided in another same film layer, whereby interference between different wirings can be avoided and the risk of short circuits can be reduced.

As an example, FIG. 10 schematically illustrates a partial component structure of a pixel circuit in the circuit layer 20. As shown in FIG. 10, optionally, the circuit layer 20 includes a first metal layer M1, a capacitor metal layer Mc, a second metal layer M2, and a third metal layer M3, wherein the first metal layer M1 may be used for forming structures such as gate metal GE of a transistor T, a lower plate CE1 of the storage capacitor Cst, and scan lines (for example, wirings for transmitting signals such as Scan1, Scan2, Scan3, and Emit); the capacitor metal layer Mc may be used for forming structures such as an upper plate CE2 of the storage capacitor Cst and an initialization signal line (transmitting the Vref signal); the second metal layer M2 may be used for forming structures such as source metal SE and drain metal DE of the transistor T, and PVDD power signal line; and the third metal layer M3 may be used for forming data signal line (transmitting Data signal).

Referring to FIG. 9, the first main line 211, the second main line 221, the initialization signal line, and the scan line may extend in a same direction, and the first branch line 212, the second branch line 222, the PVDD power signal line, and the data signal line may extend in another same direction.

Further, optionally, the first main line 211 and the second main line 221 are located in the capacitor metal layer Mc, and the first branch line 212 and the second branch line 222 are located in the third metal layer M3. Both the first metal layer M1 and the capacitor metal layer Mc have signal lines extending in the same direction as the first main line 211 and the second main line 221, but since the structure of the capacitor metal layer Mc is relatively simple, arranging the first main line 211 and the second main line 221 on the capacitor metal layer Mc may reduce wiring difficulty. Similarly, both the second metal layer M2 and the third metal layer M3 have signal lines extending in the same direction as the first branch line 212 and the second branch line 222, but since the structure of the third metal layer M3 is relatively simple, arranging the first branch line 212 and the second branch line 222 on the third metal layer M3 may reduce wiring difficulty. In addition, since a distance between the capacitor metal layer Mc and the third metal layer M3 is relatively small, providing the first main line 211 and the second main line 221 on the capacitor metal layer Mc, and providing the first branch line 212 and the second branch line 222 on the third metal layer M3 may reduce the difficulty in via-hole connections therebetween.

Referring to FIG. 8, the first branch line 212 may be electrically connected to the first-type cathode 331 by via-hole, such that a contact area between the first-type power line 21 and the first-type cathode 331 may be increased, and the connection reliability may be improved. Moreover, voltage drop loss of the first cathode signal during transmission may be reduced, i.e., the IR drop of the first-type power line 21 may be reduced, and the power consumption may be reduced. The via-hole position may be located on at least one of the display area AA and the non-display area NA, and the number of via-holes may be one or more, which is not specifically defined by the embodiments of the present application. FIG. 8 illustrates a plurality of via-holes and some via-holes are located in the display area AA and some other via-holes are located in the non-display area NA as an example. Similarly, referring to FIG. 9, the second branch line 222 may be electrically connected to the second-type cathode 332 by via-hole. The via-hole position may be located on at least one of the display area AA and the non-display area NA, and the number of via-hole may be one or more, which is not specifically defined by the embodiments of the present application.

It should also be noted that, the film layer structure of the display panel and the film layers in which the first main line 211, the second main line 221, the first branch line 212, and the second branch line 222 are disposed shown in FIG. 10 are only for illustration, and the film layer structure of the circuit layer of the display panel is not limited thereto. An appropriate film layer may be selected for forming the first main line, the second main line, the first branch line, and the second branch line according to the actual film layer structure, and the embodiments of the present application are not limited thereto.

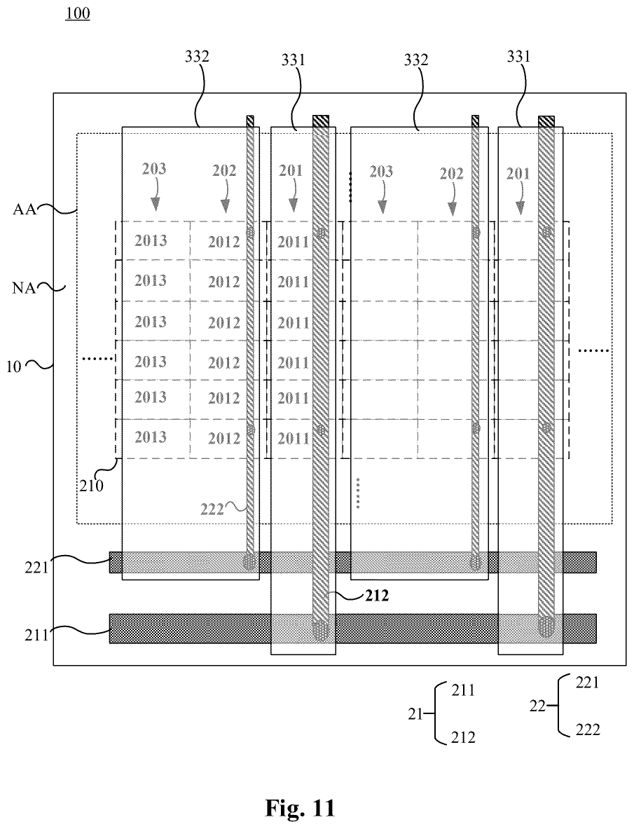

FIG. 11 is a top view of another display panel according to an embodiment of the present application. As shown in FIG. 11, optionally, the circuit layer 20 includes a plurality of pixel circuits 210 (FIG. 11 represents an arrangement area of a pixel circuit with a dashed line box) which include first-type pixel circuits 2011 and second-type pixel circuits 2012. A plurality of first-type pixel circuits 2011 arranged along the extension direction of the first branch line 212 constitute first circuit groups 201, and a plurality of second-type pixel circuits 2012 arranged along the extension direction of the second branch line 222 constitute second circuit groups 202. A number of the first branch lines 212 is equal to a number of the first circuit groups 201, and a number of the second branch lines 222 is less than or equal to a number of the second circuit groups 202.

As shown in FIGS. 9 and 11, the first-type pixel circuits 2011 are configured to drive the OLED elements corresponding to the first-type light-emission units 321 to emit light, and the first-type pixel circuits 2011 may be provided in one-to-one correspondence with this OLED elements. The second-type pixel circuits 2012 are configured to drive the OLED elements corresponding to the second-type light-emission units 322 to emit light, and the second-type pixel circuits 2012 may be provided in one-to-one correspondence with this OLED elements.

Further, for any cathode power line, the more the number of branch lines connected to the main line is, the lower the impedance of the cathode power line is, and the lower the power consumption thereof will be. However, since the branch lines pass through the display area, and the pixel circuits are provided in the display area in the circuit layer, a structure of the pixel circuit is relatively complicated and the free space is limited. Thus, the number of branch lines may be set less than or equal to the number of corresponding circuit groups. Specifically, for the first branch lines 212, the number of the first branch lines 212 may be less than or equal to the number of the first circuit groups 201. For the second branch lines 222, the number of the second branch lines 222 may be less than or equal to the number of the second circuit groups 202 so as to reduce wiring difficulty.

Further, with reference to the above explanation, considering that the influence of the first-type power line 21 on power consumption is relatively large and the influence of the second-type power line 22 on power consumption is relatively small, in specific implementation, for the first branch lines 212, the number of the first branch lines 212 may be set to be equal to the number of the first circuit groups 201 to reduce the impedance of the first-type power line 21 as much as possible, reduce the power consumption generated by the cathode power line 20a as much as possible, and finally reduce the power consumption of the display panel as much as possible.

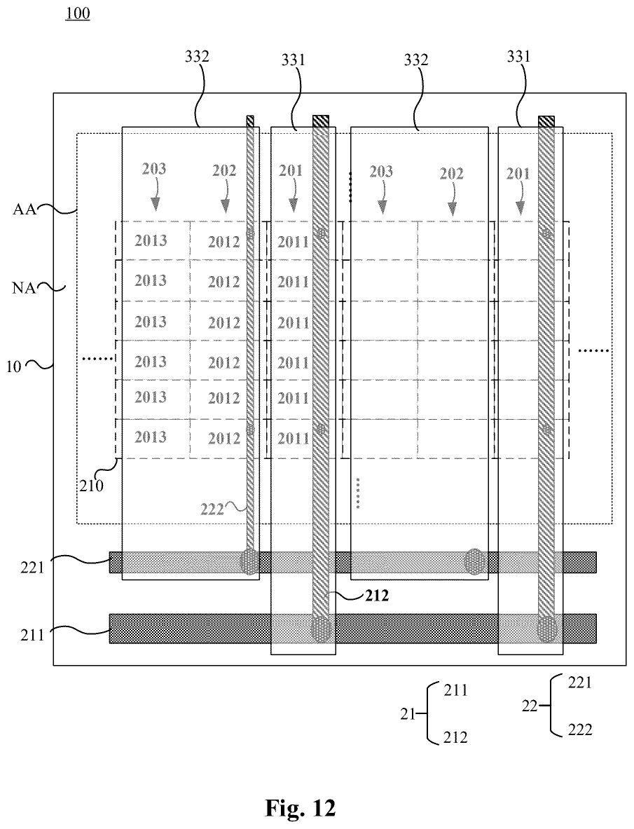

For the second branch lines 222, the number of the second branch lines 222 may be set to be less than or equal to the number of the second circuit groups 202 according to actual design requirements. As an example, FIG. 11 illustrates that the number of the second branch lines 222 is equal to the number of the second circuit groups 202. FIG. 12 is a top view of another display panel according to an embodiment of the present application. As shown in FIG. 12, in other embodiments, the number of the second branch lines 222 may be set less than the number of the second circuit groups 202.

Further, referring to FIG. 12, when the number of the second branch lines 222 is less than the number of the second circuit groups 202, optionally, the number of the second branch lines 222 is one-half of the number of the second circuit groups 202, and the second branch lines 222 are arranged side by side at equal intervals.

In this manner, not only the impedance and power consumption of the second-type power line 22 can be reduced, but also the number of wirings and thus the wiring difficulty can be reduced. Moreover, the metal structure inside the panel has certain reflectivity. Thus, by setting the second branch lines 222 side by side at equal intervals, the structural uniformity inside the panel can be improved, the uniformity of visual effects can be ensured, and user experience can be improved.

Referring to FIG. 12, optionally, an orthographic projection of the first branch line 212 on the substrate 10 overlaps an orthographic projection of an area of the first circuit group 201 on the substrate 10.

Referring to FIG. 12, since the orthographic projection of the area of the first circuit group 201 overlaps an orthographic projection of an area of the first-type cathode 331, providing the orthographic projection of the first branch line 212 overlapping the orthographic projection of the area of the first circuit group 201 may facilitate electrical connection between the first branch line 212 and the first-type cathode 331 by via-holes, thereby increasing a contact area between the first-type power line 21 and the first-type cathode 331, improving connection reliability, reducing IR drop of the first-type power line 21, and finally reducing power consumption thereof.

It should be noted that, the aforesaid pixel circuits 210 include first-type pixel circuits 2011 and second-type pixel circuits 2012, may be a situation that, the pixel circuits 210 include only first-type pixel circuits 2011 and second-type pixel circuits 2012, or a situation that, in addition to first-type pixel circuits 2011 and second-type pixel circuits 2012, the pixel circuits 210 further include other types of pixel circuits, which may be specifically determined according to the number of types of OLED elements. For example, in a case shown in FIG. 1, where the display panel includes only two types of organic light-emission units 320, i.e., two types of OLED elements, the pixel circuits 210 may include only first-type pixel circuits 2011 and second-type pixel circuits 2012; and in another case shown in FIGS. 5 to 9, where the display panel includes three types of organic light-emission units 320, the pixel circuits 210 may include three types of pixel circuits. The arrangement of the second branch lines 222 and the structure of the display panel will be described in more detail below by taking the aforesaid latter case as an example.

As shown in FIGS. 9 and 11, when the organic light-emission units include the first-type light-emission units 321, the second-type light-emission units 322, and the third-type light-emission units 323, optionally, in addition to the first-type pixel circuits 2011 and the second-type pixel circuits 2012, the pixel circuits 210 further include third-type pixel circuits 2013, and a plurality of third-type pixel circuits 2013 arranged along the extension direction of the second branch line 222 constitute a third circuit group 203.

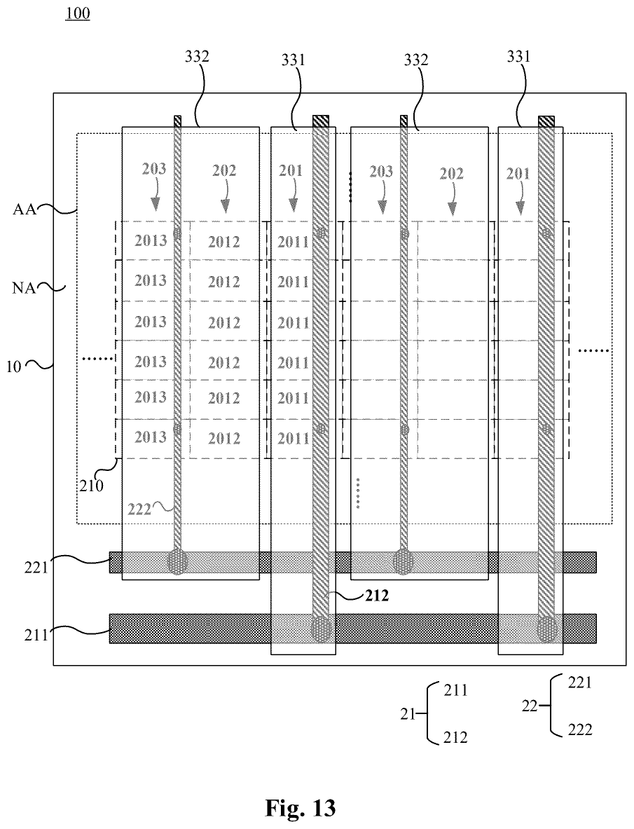

Further, referring to FIG. 9, when each of the second-type cathodes 332 covers at least one second-type light-emission unit 322 and at least one third-type light-emission unit 323, optionally, an orthographic projection of the second branch line 222 on the substrate 10 overlaps an orthographic projection of an area of the second circuit group 202 on the substrate 10 (see FIG. 11), or, the orthographic projection of the second branch line 222 on the substrate 10 overlaps an orthographic projection of an area of the third circuit group 203 on the substrate 10 (see FIG. 13, which is a top view of another display panel according to an embodiment of the present application).

Specifically, referring to FIGS. 11 to 13, since an orthographic projection of an area of the second-type cathode 332 overlaps the orthographic projection of the area of the second circuit group 202 and the third circuit group 203, providing the orthographic projection of the second branch line 222 overlapping the orthographic projection of the area of the second circuit group 202 (FIG. 11 or FIG. 12), or the orthographic projection of the second branch line 222 overlapping the orthographic projection of the area of the third circuit group 203 (FIG. 13) may facilitate electrical connection between the second branch line 222 and the second-type cathode 332 by via-holes, i.e., facilitate electrical connection between the second-type power line 22 and the second-type cathode 332 by via-holes, thereby increasing a contact area between the second-type power line 22 and the second-type cathode 332, improving connection reliability, reducing IR drop of the second-type power line 22, and finally reducing power consumption thereof.

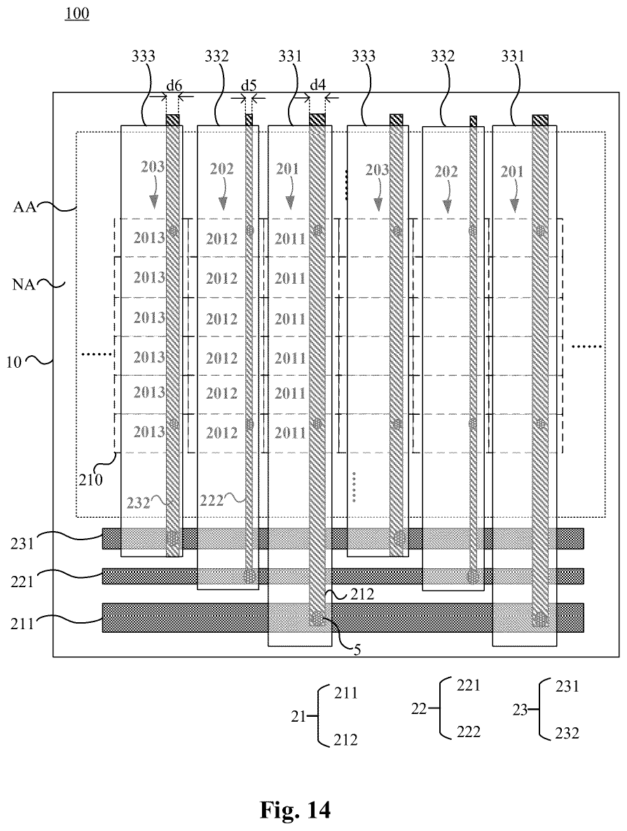

FIG. 14 is a top view of another display panel according to an embodiment of the present application. Comparing FIG. 7 and FIG. 14, when the cathode layer 33 includes first-type cathodes 331, second-type cathodes 332, and third-type cathodes 333, one first-type cathode 331 covers at least one first-type light-emission unit 321, one second-type cathode 332 covers at least one second-type light-emission unit 322, and one third-type cathode 333 covers at least one third-type light-emission unit 323. The cathode power lines 20a include the first-type power line 21, the second-type power line 22 and the third-type power line 23. The first-type cathode 331 is electrically connected to the first-type power line 21, the second-type cathode 332 is electrically connected to the second-type power line 22, and the third-type cathode 333 is electrically connected to the third-type power line 23. Optionally, in addition to the third main line 231, the third-type power line 23 further includes a plurality of third branch lines 232. An extension direction of the third branch lines 232 intersects an extension direction of the third main line 231, and each of the plurality of third branch lines 232 is electrically connected to the third main line 231. The third main line 231 is located in the non-display area NA, and the third branch lines 232 pass through the display area AA. A number of the third branch lines 232 is less than or equal to a number of the third circuit groups 203. An orthographic projection of the second branch line 222 on the substrate 10 overlaps an orthographic projection of an area of the second circuit group 202 on the substrate 10, and an orthographic projection of the third branch line 232 on the substrate 10 overlaps an orthographic projection of an area of the third circuit group 203 on the substrate 10. The first branch line 212 may be configured in a same manner as that described above.

Specifically, when the number of types of organic light-emission units, the number of types of cathodes, and the number of types of cathode power lines are arranged in one-to-one correspondence, the third-type power line 23 may be formed by electrically connecting the third main line 231 and the plurality of third branch lines 232 with reference to the arrangement of the first-type power line 21 and the second-type power line 22 described above. In this manner, the impedance and power consumption of the third-type power line 23 can be further reduced, and the power consumption of the display panel can be further reduced accordingly.

Further, when the number of types of organic light-emission units, the number of types of cathodes, and the number of types of cathode power lines are arranged in one-to-one correspondence, providing the orthographic projection of the first branch line 212 overlapping the orthographic projection of the area of the first circuit group 201, the orthographic projection of the second branch line 222 overlapping the orthographic projection of the area of the second circuit group 202, and the orthographic projection of the third branch line 232 overlapping the orthographic projection of the area of the third circuit group 203 may facilitate electrical connection between branch lines and corresponding cathodes by via-holes, thereby increasing contact areas between the cathode power lines 20a and corresponding cathodes, improving connection reliability, reducing IR drop of the cathode power lines, and finally reducing power consumption thereof.

Referring to FIG. 14, optionally, the first branch line 212, the second branch line 222, and the third branch line 232 are located in a same film layer and have a same extension direction. The specific film layer position may be configured in a same manner as that described above, which will not be repeated here.

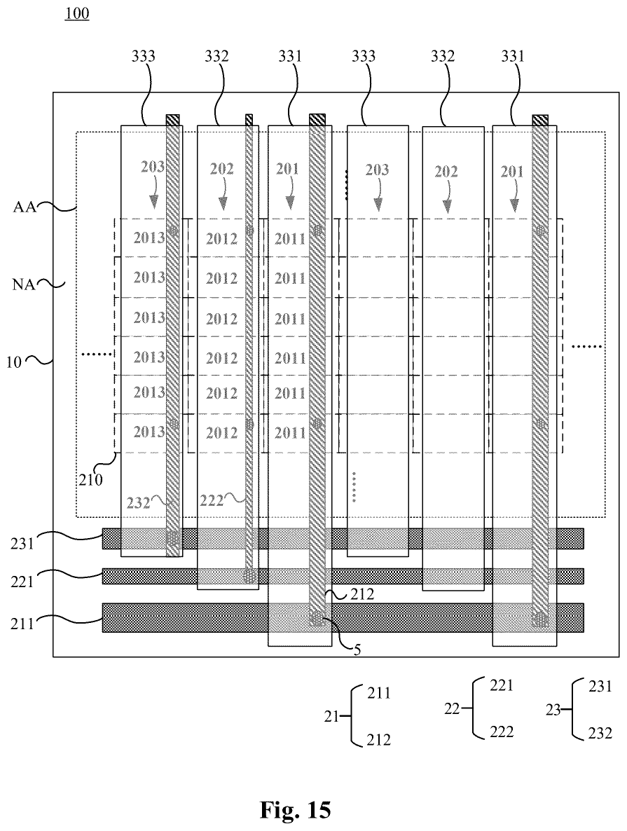

FIG. 15 is a top view of another display panel according to an embodiment of the present application. As shown in FIG. 15, optionally, when the number of the third branch lines 232 is less than the number of the third circuit groups 203, the number of the third branch lines 232 may be one-half of the number of the third circuit groups 203, and the third branch lines 232 are arranged side by side at equal intervals. In this manner, not only the impedance and power consumption of the third-type power line 23 can be reduced, but also the number of wirings and the wiring difficulty can be reduced. In addition, by providing the third branch lines 232 side by side at equal intervals, the uniformity of visual effects can be ensured.

Referring to FIG. 14, optionally, the width d6 of the third branch line 232 is less than the width d4 of the first branch line 212, and the width d6 of the third branch line 232 is larger than or equal to the width d5 of the second branch line 222.

Similar to the design concept of widths of the first main line, the second main line and the third main line described above, by designing the width of the third branch line to be less than the width of the first branch line while larger than or equal to the width of the second branch line, power consumption generated on the cathode power line can be reduced to a larger extent, and power consumption of the display panel can be reduced to a larger extent. For example, this design may be applied to a case where the first-type light-emission units are blue light-emission units, the second-type light-emission units are green light-emission units, and the third-type light-emission units are red light-emission units.

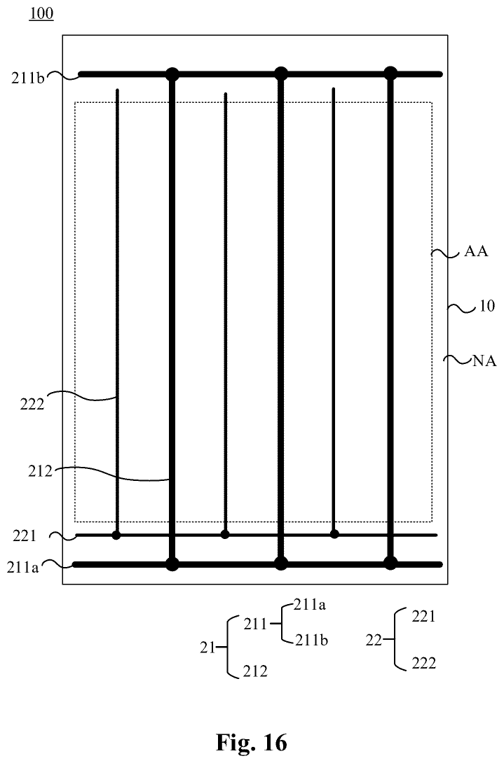

FIG. 16 is a top view of another display panel according to an embodiment of the present application. As shown in FIG. 16, optionally, the first main line 211 includes a first sub-portion 211a and a second sub-portion 211b, and the first sub-portion 211a and the second sub-portion 211b are located on two opposite sides of the first branch line 212 respectively.

In this manner, the first cathode signal may be simultaneously received by the first sub-portion 211a and the second sub-portion 211b, which may facilitate improving signal uniformity of the first cathode signal at different areas, thereby increasing a contact area between the first-type power line 21 and the first-type cathode, improving connection reliability, reducing IR drop of the first-type power line 21, and finally reducing power consumption thereof.

It should be noted that, if the first main line 211 is located on a side of the first branch line 212, and the width of the first main line 211 is d1, then a sum of widths of the first sub-portion 211a and the second sub-portion 211b may be larger than or equal to d1, and the embodiments of the present application are not limited thereto. Since area for forming the first main line 211 increases, it may facilitate achieving the sum of widths of the first sub-portion 211a and the second sub-portion 211b being larger than d1, thereby further reducing the impedance of the first-type power line.

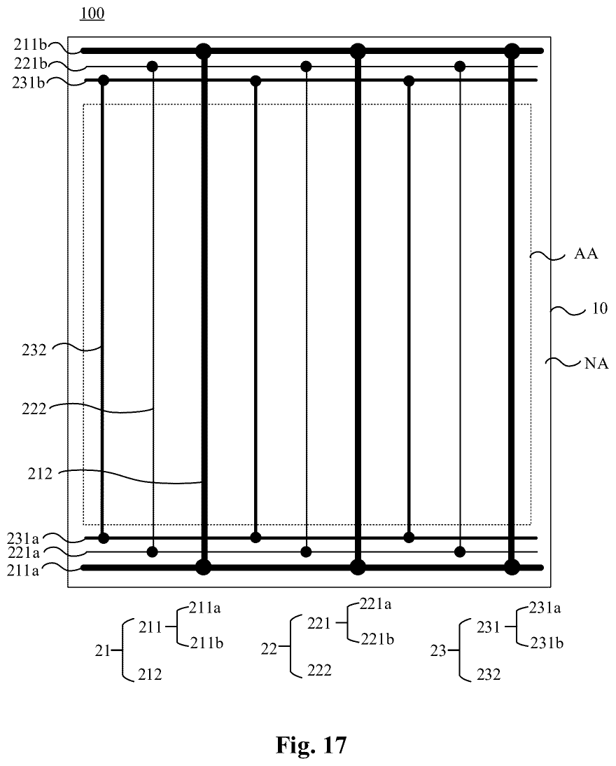

FIG. 17 is a top view of another display panel according to an embodiment of the present application. As shown in FIG. 17, optionally, the second main line 221 includes a third sub-portion 221a and a fourth sub-portion 221b, and the third sub-portion 221a and the fourth sub-portion 221b are located on two opposite sides of the second branch line 222 respectively.

In this manner, the second cathode signal may be simultaneously received by the third sub-portion 221a and the fourth sub-portion 221b, which may facilitate improving signal uniformity of the second cathode signal at different areas, thereby increasing a contact area between the second-type power line 22 and the second-type cathode, improving connection reliability, reducing IR drop of the second-type power line 22, and finally reducing power consumption thereof.

It should be noted that, if the second main line 221 is located on a side of the second branch line 222, and the width of the second main line 221 is d2, then a sum of widths of the third sub-portion 221a and the fourth sub-portion 221b may be larger than or equal to d2, and the embodiments of the present application are not limited thereto. Since area for forming the second main line 221 increases, it may facilitate achieving the sum of widths of the third sub-portion 221a and the fourth sub-portion 221b being larger than d2, thereby further reducing the impedance of the second-type power line.

Referring to FIG. 17, optionally, the third main line 231 includes a fifth sub-portion 231a and a sixth sub-portion 231b, and the fifth sub-portion 231a and the sixth sub-portion 231b are located on two opposite sides of the third branch line 232 respectively.

In this manner, the third cathode signal may be simultaneously received by the fifth sub-portion 231a and the sixth sub-portion 231b, which may facilitate improving signal uniformity of the third cathode signal at different areas, thereby increasing a contact area between the third-type power line 23 and the third-type cathode, improving connection reliability, reducing IR drop of the third-type power line 23, and finally reducing power consumption thereof.

It should be noted that, if the third main line 231 is located on a side of the third branch line 232, and the width of the third main line 231 is d3, then a sum of widths of the fifth sub-portion 231a and the sixth sub-portion 231b may be larger than or equal to d3, and the embodiments of the present application are not limited thereto. Since area for forming the third main line 231 increases, it may facilitate achieving the sum of widths of the fifth sub-portion 231a and the sixth sub-portion 231b being larger than d3, thereby further reducing the impedance of the third-type power line.

In a word, the arrangement of the cathode layer and the cathode power lines of the display panel is illustrated in detail in the above embodiments taking as an example that the organic light-emission units with the same light-emission color are arranged side by side in a same direction, and the organic light-emission units with different light-emission colors are alternately arranged in the other intersecting direction. For example, as shown in FIG. 5, a plurality of first-type light-emission units 321, a plurality of second-type light-emission units 322, and a plurality of third-type light-emission units 323 each are arranged side by side in the column direction, and the first-type light-emission units 321, the second-type light-emission units 322, and the third-type light-emission units 323 are alternately arranged in the row direction. As described above, embodiments of the present application are not limited by the pixel arrangement pattern, and embodiments of the present application will be briefly described below taking another pixel arrangement pattern as an example.

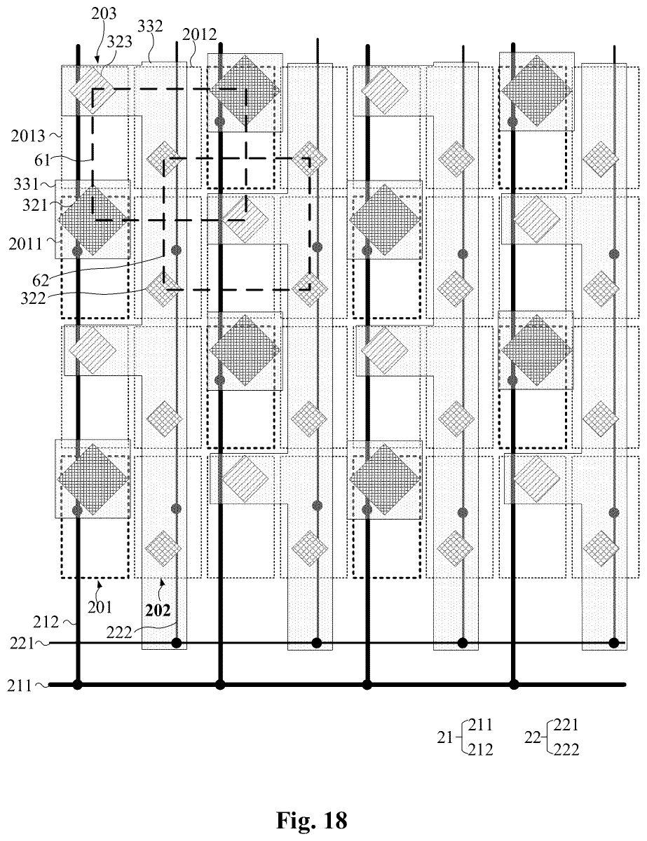

For example, FIG. 18 is a top view of another display panel according to an embodiment of the present application. As shown in FIG. 18, taking the first-type light-emission units 321 being blue light-emission units, the second-type light-emission units 322 being green light-emission units, and the third-type light-emission units 323 being red light-emission units as an example, optionally, a plurality of first-type light-emission units 321 and a plurality of third-type light-emission units 323 constitute a first virtual quadrilateral 61; a center of the first-type light-emission unit 321 is located on a first vertex of the first virtual quadrilateral 61, and a center of the third-type light-emission unit 323 is located on a second vertex of the first virtual quadrilateral 61; the first vertex and the second vertex are arranged alternately and spaced from each other; that is, the first-type light-emission units 321 are located on the vertexes of one diagonal of the first virtual quadrilateral, the third-type light-emission units 323 are located on the vertexes of the other diagonal of the first virtual quadrilateral, and the second-type light emission unit 322 is located inside the first virtual quadrilateral 61; the plurality of second-type light-emission units 322 constitute a second virtual quadrilateral 62; centers of the plurality of second-type light-emission units 322 are respectively located on vertexes of the second virtual quadrilateral 62; and the first-type light-emission unit 321 or the third-type light-emission unit 323 is located inside the second virtual quadrilateral 62. In this manner, the overall arrangement is similar to “diamond” pixel arrangement. Through the above arrangement, a good rendering effect can be ensured, and the color display effect of the display panel can be further improved.

Accordingly, the pixel circuit includes first-type pixel circuits 2011, second-type pixel circuits 2012, and third-type pixel circuits 2013, wherein the first-type pixel circuits 2011 are arranged corresponding to OLED elements where the first-type light-emission units 321 are located, the second-type pixel circuits 2012 are arranged corresponding to OLED elements where the second-type light-emission units 322 are located, and the third-type pixel circuits 2013 are arranged corresponding to OLED elements where the third-type light-emission units 323 are located. In particular, based on the above arrangement of the organic light-emission units, the first-type pixel circuits 2011 and the third-type pixel circuits 2013 are alternately arranged in the extension direction of the first branch line 212, and there is an overlap between the area of the first circuit group 201 and the area of the third circuit group 203.

Further, about the arrangement of the cathode layer and the cathode power lines, as shown in FIG. 18, the cathode layer includes at least a first-type cathode 331 and a second-type cathode 332, and the first-type cathode 331 and the second-type cathode 332 are arranged spaced from each other; the cathode power line 20a in the circuit layer includes at least a first-type power line 21 and a second-type power line 22; the first-type cathode 331 is electrically connected to the first-type power line 21, and the second-type cathode 332 is electrically connected to the second-type power line 22; the first-type power line 21 receives a first cathode signal, and the second-type power line 22 receives a second cathode signal, an absolute value of voltage of the first cathode signal being larger than an absolute value of voltage of the second cathode signal; and the first-type power line 21 includes a first main line 211, and the second-type power line 22 includes a second main line 221, a width of the first main line 211 being larger than a width of the second main line 221 (indicated by line weight variations).

As shown in FIG. 18, in the present embodiment, since the respective first-type light-emission units 321 are arranged spaced from each other, each of the first-type cathodes 331 may cover only one first-type light-emission unit 321, and the respective first-type cathodes 331 are arranged spaced from each other as well. Then, by providing that the first-type power line 21 includes the first main line 211 and the first branch line 212 that are electrically connected to each other, the first branch line 212 and the first-type cathode 331 may be electrically connected to each other by via-hole, so as to realize electrical connection between the first-type cathode 331 and the first-type power line 21.

As shown in FIG. 18, optionally, one second-type cathode 332 covers at least one second-type light-emission unit 322 and at least one third-type light-emission unit 323. FIG. 18 illustrates an example in which one second-type cathode 332 simultaneously covers a plurality of second-type light-emission units 322 and a plurality of third-type light-emission units 323. At this time, the second-type power line 22 may include only the second main line 221, or may be constituted by the second main line 221 and the second branch line 222 electrically connected to each other, and FIG. 18 illustrates only the latter one as an example. This design may facilitate reducing the impedance of the second-type power line 22 and improving connection reliability between the second-type power line 22 and the second-type cathode 332.

As shown in FIG. 18, optionally, a number of the first branch lines 212 is equal to a number of the first circuit groups 201, and a number of the second branch lines 222 is equal to a number of the second circuit groups 202. In other embodiments, the number of the second branch lines 222 may less than the number of the second circuit groups 202. For example, it may be set that, the number of the second branch lines 222 is one-half of the number of the second circuit groups 202, and the second branch lines 222 are arranged side by side at equal intervals.

As shown in FIG. 18, optionally, an orthographic projection of the first branch line 212 on the substrate overlaps an orthographic projection of an area of the first circuit group 201 on the substrate. About the arrangement position of the first branch line 212, when each of the second-type cathodes 332 covers at least one second-type light-emission unit 322 and at least one third-type light-emission unit 323, optionally, an orthographic projection of the second branch line 222 on the substrate overlaps an orthographic projection of an area of the second circuit group 202 on the substrate (see FIG. 18). In other embodiments, the orthographic projection of the second branch line 222 on the substrate may overlap an orthographic projection of an area of the third circuit group 203 on the substrate. In FIG. 18, by providing the orthographic projection of the second branch line 222 on the substrate overlapping the orthographic projection of the area of the second circuit group 202 on the substrate, wiring difficulty can be reduced.

Referring to FIG. 18, optionally, a width of the first branch line 212 is larger than a width of the second branch line 222 (indicated by line weight variations). In addition, optionally, the first branch line 212 and the second branch line 222 are located in a same film layer and have a same extension direction.

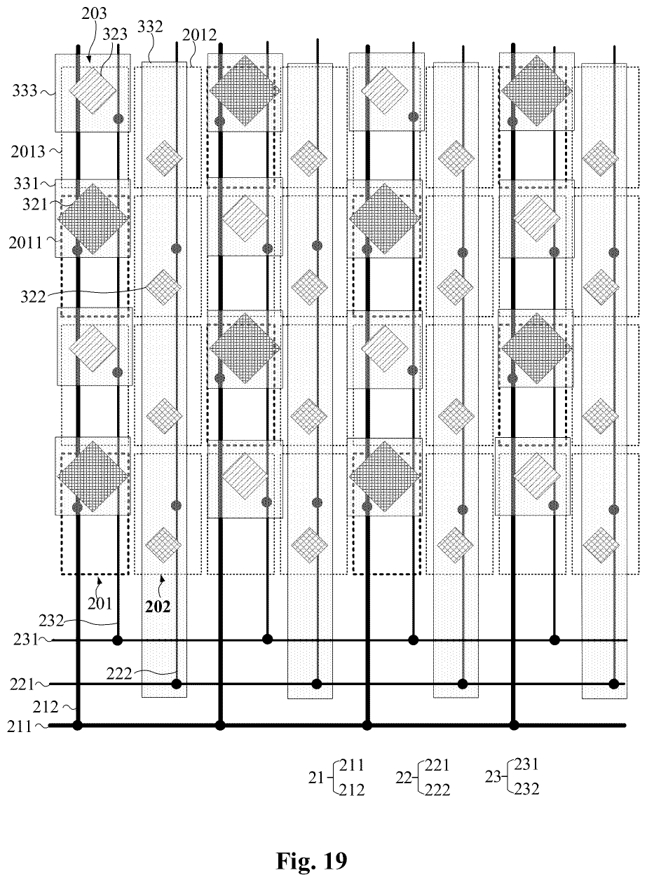

FIG. 19 is a top view of another display panel according to an embodiment of the present application, which has a same pixel arrangement pattern in the display panel as shown in FIG. 18, except that the cathode layer includes not only the first-type cathode 331 and the second-type cathode 332, but also the third-type cathode 333. As shown in FIG. 19, each of the first-type cathodes 331 covers one first-type light-emission unit 321, each of the second-type cathodes 332 covers a plurality of second-type light-emission units 322, and each of the third-type cathodes 333 covers one third-type light-emission unit 323; and the first-type cathode 331, the second-type cathode 332, and the third-type cathode 333 are arranged spaced from each other. Correspondingly, the cathode power line includes not only the first-type power line 21 and the second-type power line 22, but also the third-type power line 23; the third-type cathode 333 is electrically connected to the third-type power line 23; the third-type power line 23 receives a third cathode signal, an absolute value of voltage of the third cathode signal being less than an absolute value of voltage of the first cathode signal; and the third-type power line 23 includes a third main line 231, a width of the third main line 231 being less than a width of the first main line 211 (indicated by line weight variations).

As shown in FIG. 19, in the present embodiment, since the respective third-type light-emission units 323 are arranged spaced from each other, each of the third-type cathodes 333 may cover only one third-type light-emission unit 323, and the respective third-type cathodes 333 are arranged spaced from each other as well. Then, by providing that the third-type power line 23 includes the third main line 231 and the third branch line 232 that are electrically connected to each other, the third branch line 232 and the third-type cathode 333 may be electrically connected to each other by via-hole, so as to realize electrical connection between the third-type cathode 333 and the third-type power line 23. Optionally, a width of the third branch line 232 is less than a width of the first branch line 212 (indicated by line weight variations).

As shown in FIG. 19, when the cathode and cathode power lines corresponding to the second-type light-emission units 322 and those corresponding to the third type light-emission units 323 are independently arranged, optionally, the number of the third branch lines 232 is less than or equal to the number of the third circuit groups 203 (FIG. 19 only illustrates that the two equal to each other as an example), and optionally, an orthographic projection of the second branch line 222 on the substrate 10 overlaps an orthographic projection of an area of the second circuit group 202 on the substrate 10, and an orthographic projection of the third branch line 232 on the substrate 10 overlaps an orthographic projection of an area of the third circuit 203 group on the substrate 10.

Referring to FIG. 19, when the first-type light-emission units 321 are blue light-emission units, the second-type light-emission units 322 are green light-emission units, and the third-type light-emission units 323 are red light-emission units, it may be set that, the absolute value of voltage of the third cathode signal is larger than or equal to the absolute value of voltage of the second cathode signal; the width of the third main line 231 is larger than or equal to the width of the second main line 221, and the width of the third branch line 232 is larger than or equal to the width of the second branch line 222, and the embodiments of the present application are not limited thereto.

In addition, it should be noted that, FIGS. 18 and 19 only illustrate that the first main line 211 is located on a side of the first branch line 212 as an example, and with reference to FIG. 17, optionally, the first main line 211 includes a first sub-portion 211a and a second sub-portion 211b located on two opposite sides of the first branch line 212 respectively. Similarly, with reference to FIG. 17, in other embodiments, it may be set that, the second main line 221 includes a third sub-portion 221a and a fourth sub-portion 221b located on two opposite sides of the second branch line 222 respectively, and the third main line 231 includes a fifth sub-portion 231a and a sixth sub-portion 231b located on two opposite sides of the third branch line 232 respectively.

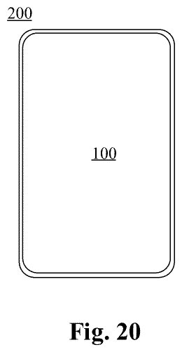

Based on the same inventive concept, an embodiment of the present application further provides a display apparatus. For example, FIG. 20 is a structural diagram of a display apparatus according to an embodiment of the present application. As shown in FIG. 20, the display apparatus 200 includes the display panel 100 according to any one of the above embodiments, and thus has the same technical effects as the above-described display panel. For similarities, reference can be made to the above embodiments, which will not be repeated here. The display apparatus 200 may be an OLED display apparatus. The display apparatus 200 according to the embodiments of the present application may be a mobile phone shown in FIG. 20, or any electronic product having a display function, including but not limited to the following categories: television, notebook computer, desktop display, tablet computer, digital camera, smart bracelet, smart glasses, vehicle display, medical equipment, industrial control equipment, touch interactive terminal, etc., and the embodiments of the present application are not particularly limited thereto.

The above-described specific embodiments do not limit the scope of protection of the present application. It will be understood by those skilled in the art that, various modifications, combinations, sub-combinations, and substitutions may be made depending on design requirements and other factors. Any modification, equivalent substitution and improvement made within the gist and principle of the present application should be included within the scope of protection of the present application.

What is claimed is:

1. A display panel, comprising:
a substrate;
a circuit layer, located on a side of the substrate, wherein
the circuit layer comprises cathode power lines, and the cathode power lines comprise at least a first-type power line and a second-type power line,
the first-type power line is configured to receive a first cathode signal, and the second-type power line is configured to receive a second cathode signal, an absolute value of voltage of the first cathode signal being larger than an absolute value of voltage of the second cathode signal,
the first-type power line comprises a first main line, and the second-type power line comprises a second main line, a width of the first main line being larger than a width of the second main line; and
a cathode layer, located at a side of the circuit layer away from the substrate, wherein
the cathode layer comprises at least first-type cathodes and second-type cathodes, the first-type cathodes being spaced from the second-type cathodes,
the first-type cathodes are electrically connected to the first-type power line, and the second-type cathode are electrically connected to the second-type power line.

2. The display panel according to claim 1, further comprising:
an anode layer, located on the side of the circuit layer away from the substrate; and
an organic light-emission layer, located on a side of the anode layer away from the substrate, the cathode layer being located on a side of the organic light-emission layer away from the substrate, wherein
the organic light-emission layer comprises a plurality of organic light-emission units, the organic light-emission units comprise at least first-type light-emission units and second-type light-emission units, a light-emission color of the first-type light-emission units is different from a light-emission color of the second-type light-emission units,
each of the first-type cathodes covers at least one of the first-type light-emission units, and each of the second-type cathodes covers at least one of the second-type light-emission units.

3. The display panel according to claim 2, wherein
the organic light-emission units further comprise third-type light-emission units, and a light-emission color of the third-type light-emission units is different from the light-emission color of the first-type light-emission units and the light-emission color of the second-type light-emission units; and
each of the second-type cathodes covers at least one of the second-type light-emission units and at least one of the third-type light-emission units.

4. The display panel according to claim 3, wherein the first-type light-emission units are blue light-emission units, the second-type light-emission units or the third-type light-emission units are green light-emission units, and the other of the second-type light-emission units and the third-type light-emission units are red light-emission units.

5. The display panel according to claim 2, wherein
the organic light-emission units further comprise third-type light-emission units, and a light-emission color of the third-type light-emission units is different from the light-emission color of the first-type light-emission units and the light-emission color of the second-type light-emission units;
the cathode layer further comprises third-type cathodes, the third-type cathodes are spaced from the first-type cathodes and the second-type cathodes, and each of the third-type cathodes covers at least one of the third-type light-emission units; and
the cathode power lines further comprise a third-type power line, the third-type cathodes are electrically connected to the third-type power line, the third-type power line is configured to receive a third cathode signal, an absolute value of voltage of the third cathode signal being less than the absolute value of voltage of the first cathode signal, and the third-type power line comprises a third main line, a width of the third main line being less than the width of the first main line.

6. The display panel according to claim 5, wherein
the first-type light-emission units are blue light-emission units, the second-type light-emission units are green light-emission units, and the third-type light-emission units are red light-emission units;
the absolute value of voltage of the third cathode signal is larger than or equal to the absolute value of voltage of the second cathode signal; and
the width of the third main line is larger than or equal to the width of the second main line.

7. The display panel according to claim 2, wherein
the first-type power line further comprises a plurality of first branch lines, an extension direction of each of the first branch lines intersects an extension direction of the first main line, and each of the plurality of first branch lines is electrically connected to the first main line; and
the display panel comprises a display area and a non-display area located on at least one side of the display area, the first main line is located in the non-display area, and the first branch lines pass through the display area.

8. The display panel according to claim 7, wherein the first main line comprises a first sub-portion and a second sub-portion, and the first sub-portion and the second sub-portion are located on two opposite sides of the first branch line respectively.

9. The display panel according to claim 7, wherein
the second-type power line further comprises a plurality of second branch lines, an extension direction of each of the second branch lines intersects an extension direction of the second main line, and each of the plurality of second branch lines is electrically connected to the second main line; and
the second main line is located in the non-display area, and the second branch lines pass through the display area.

10. The display panel according to claim 9, wherein the second main line comprises a third sub-portion and a fourth sub-portion, and the third sub-portion and the fourth sub-portion are located on two opposite sides of the second branch line respectively.

11. The display panel according to claim 9, wherein a width of the first branch lines is larger than a width of the second branch lines.

12. The display panel according to claim 9, wherein the first branch lines and the second branch lines are located in a same film layer and have a same extension direction.

13. The display panel according to claim 9, wherein
the circuit layer comprises a plurality of pixel circuits, the plurality of pixel circuits comprise first-type pixel circuits and second-type pixel circuits, a plurality of the first-type pixel circuits arranged along the extension direction of one of the first branch lines constitute a first circuit group, and a plurality of the second-type pixel circuits arranged along the extension direction of one of the second branch lines constitute a second circuit group; and
a number of the first branch lines is equal to a number of the first circuit groups, and a number of the second branch lines is less than or equal to a number of the second circuit groups.

14. The display panel according to claim 13, wherein the number of the second branch lines is one-half of the number of the second circuit groups, and the second branch lines are arranged side by side at equal intervals.

15. The display panel according to claim 13, wherein an orthographic projection of the one of the first branch lines on the substrate overlaps an orthographic projection of an area of the first circuit group on the substrate.

16. The display panel according to claim 13, wherein
the organic light-emission units comprise third-type light-emission units, and each of the second-type cathode covers at least one of the second-type light-emission units and at least one of the third-type light-emission units;
the pixel circuits further comprise third-type pixel circuits, and a plurality of the third-type pixel circuits arranged along the extension direction of one of the second branch lines constitute a third circuit group; and
an orthographic projection of one of the second branch lines on the substrate overlaps an orthographic projection of an area of the second circuit group on the substrate, or an orthographic projection of one of the second branch lines on the substrate overlaps an orthographic projection of an area of the third circuit group on the substrate.

17. The display panel according to claim 13, wherein
the organic light-emission units comprise third-type light-emission units, the cathode layer comprises third-type cathodes, each of the third-type cathodes covers at least one of the third-type light-emission units, the cathode power lines comprise a third-type power line, the third-type cathodes are electrically connected to the third-type power line, and the third-type power line comprises a third main line;
the third-type power line further comprises a plurality of third branch lines, an extension direction of each of the third branch lines intersects an extension direction of the third main line, each of the plurality of third branch lines is electrically connected to the third main line, and the third main line is located in the non-display area, and the third branch lines pass through the display area;
the pixel circuits further comprise third-type pixel circuits, a plurality of the third-type pixel circuits arranged along the extension direction of one of the third branch lines constitute a third circuit group, and a number of the third branch lines is less than or equal to a number of the third circuit groups; and
an orthographic projection of one of the second branch lines on the substrate overlaps an orthographic projection of an area of the second circuit group on the substrate, and an orthographic projection of one of the third branch lines on the substrate overlaps an orthographic projection of an area of the third circuit group on the substrate.

18. The display panel according to claim 17, wherein a width of the third branch lines is less than a width of the first branch lines, and a width of the third branch lines is larger than or equal to a width of the second branch lines.

19. The display panel according to claim 17, wherein the third main line comprises a fifth sub-portion and a sixth sub-portion, and the fifth sub-portion and the sixth sub-portion are located on two opposite sides of the third branch line respectively.

20. A display apparatus comprising a display panel, comprising:
a substrate;
a circuit layer, located on a side of the substrate, wherein
the circuit layer comprises cathode power lines, and the cathode power lines comprise at least a first-type power line and a second-type power line,
the first-type power line is configured to receive a first cathode signal, and the second-type power line is configured to receive a second cathode signal, an absolute value of voltage of the first cathode signal being larger than an absolute value of voltage of the second cathode signal,
the first-type power line comprises a first main line, and the second-type power line comprises a second main line, a width of the first main line being larger than a width of the second main line; and
a cathode layer, located at a side of the circuit layer away from the substrate, wherein
the cathode layer comprises at least first-type cathodes and second-type cathodes, the first-type cathodes being spaced from the second-type cathodes,
the first-type cathodes are electrically connected to the first-type power line, and the second-type cathodes are electrically connected to the second-type power line.
